(19) United States
(12) Patent Application Publication
(10) Pub. No.: US 2025/0142967 A1
(43) Pub. Date: May 1, 2025

(54) DISPLAY PANEL, MANUFACTURING METHOD OF THE SAME, AND ELECTRONIC DEVICE

(71) Applicant: SAMSUNG ELECTRONICS CO., LTD., Suwon-si (KR)

(72) Inventors: LUHING HU, Suwon-si (KR); Sangwon KIM, Suwon-si (KR); Joonseok Kim, Suwon-si (KR); Joonyun Kim, Suwon-si (KR); JUNHEE CHOI, Suwon-si (KR)

(21) Appl. No.: 18/914,400

(22) Filed: Oct. 14, 2024

(30) Foreign Application Priority Data
Oct. 31, 2023 (KR) 10-2023-0148455

(51) Int. Cl. H01L 27/12; H01L 25/065; H01L 27/15

(52) U.S. Cl. CPC H10D 86/60; H01L 25/0657; H10D 86/021; H10D 86/451; H10H 29/142

(57) ABSTRACT

A display panel includes a substrate, a gate electrode disposed on the substrate, a two-dimensional semiconductor material layer overlapping the gate electrode, a source electrode and a drain electrode electrically connected to the two-dimensional semiconductor material layer, a first electrode of a micro light-emitting diode electrically connected to the drain electrode, an active layer electrically connected to the first electrode of the micro light-emitting diode, where the active layer includes a quantum well layer surrounded by an ion-doped insulating partition, and a second electrode of the micro light-emitting diode electrically connected to the active layer.

### CROSS-REFERENCE TO RELATED APPLICATION

This application claims priority to Korean Patent Application No. 10-2023-0148455 filed on Oct. 31, 2023, and all the benefits accruing therefrom under 35 U.S.C. § 119, the content of which in its entirety is herein incorporated by reference.

### BACKGROUND

### (a) Field

Embodiments of the disclosure relate to a display panel, a manufacturing method of the display panel, and an electronic device including the display panel.

### (b) Description of the Related Art

Electronic devices including display panels such as liquid crystal display panels or organic light-emitting diode display panels are widely used in various fields. Recently, technology for manufacturing display panels using micro light-emitting diodes as light emitters has been researched.

### SUMMARY

To manufacture display panels using micro light-emitting diodes, a complex process may be because the micro light-emitting diodes may be manufactured on a separate substrate and then transferred to the display panel or aligned on the display panel through bonding of individual micro light-emitting diodes. In addition, as the number of pixels in the display panel increases and the dimension of the micro light-emitting diode decreases, alignment of the micro light-emitting diodes on the display panel becomes difficult, which limits the implementation of high-resolution and high-performance display panels.

An embodiment attempts to provide a display panel capable of simplifying processes, and realizing high resolution and good performance.

Another embodiment attempts to provide a manufacturing method for the display panel.

A still another embodiment attempts to provide an electronic device including the display panel.

An embodiment of a display panel according to the invention includes a substrate, a gate electrode disposed on the substrate, a two-dimensional semiconductor material layer overlapping the gate electrode, a source electrode and a drain electrode electrically connected to the two-dimensional semiconductor material layer, a first electrode of a micro light-emitting diode electrically connected to the drain electrode, an active layer electrically connected to the first electrode of the micro light-emitting diode, where the active layer includes a quantum well layer surrounded by an ion-doped insulating partition, and a second electrode of the micro light-emitting diode electrically connected to the active layer.

In an embodiment, the display panel may further include a first insulation layer disposed between the first electrode of the micro light-emitting diode and the two-dimensional semiconductor material layer and contacting a lower portion or an upper portion of the two-dimensional semiconductor material layer, and a second insulation layer surrounding a side surface of the two-dimensional semiconductor material layer, where the second insulation layer may be thicker than the two-dimensional semiconductor material layer.

In an embodiment, a thickness of the second insulation layer may be 3 times to 100 times of a thickness of the two-dimensional semiconductor material layer.

In an embodiment, one of the first insulation layer and the second insulation layer may include silicon oxide, silicon nitride, silicon oxynitride, or a combination thereof, and the other of the first insulation layer and the second insulation layer may include oxide, nitride, oxynitride, or a combination thereof that may include hafnium (Hf), aluminum (AI), lanthanum (La), barium (Ba), strontium (Sr), zirconium (Zr), yttrium (Y), calcium (Ca), or a combination thereof.

In an embodiment, the two-dimensional semiconductor material layer may include metal chalcogenide, and have a monocrystalline, pseudo-monocrystalline, or polycrystalline structure.

In an embodiment, the active layer may further include an N-type layer located in one of an upper portion and a lower portion of the quantum well layer, and a P-type layer located in the other of the upper portion and the lower portion of the quantum well layer, where at least one selected from the N-type layer or the P-type layer may be surrounded by the ion-doped insulating partition.

In an embodiment, the ion-doped insulating partition may include GaN, InGaN, or a combination thereof doped with nitrogen ions, argon ions, boron ions, phosphorus ions, arsenic ions, or a combination thereof.

In an embodiment, the display panel may further include an interlayer insulating layer disposed between the substrate and the source electrode, and a conductive interconnect disposed in the interlayer insulating layer and connecting the source electrode and a wire to each other.

An embodiment of a display panel includes first, second, and third thin film transistors disposed in first, second, and third subpixels, respectively, where the first, second, and third subpixels are adjacent to each other, first, second, and third micro light-emitting diodes located in the first, second, and third subpixels, respectively, and electrically connected to the first, second, and third thin film transistors, respectively, an ion-doped insulating partition partitioning the first, second, and third micro light-emitting diodes, and an insulation layer disposed between the first, second, and third thin film transistors and the first, second, and third micro light-emitting diodes and including a plurality of pocket patterns defined therein, where each of the first, second, and third thin film transistors may include a two-dimensional semiconductor material layer, and where the two-dimensional semiconductor material layer may be disposed in the pocket pattern of the insulation layer.

In an embodiment, the insulation layer may include a first insulation layer disposed on an entire surface between the first, second, and third thin film transistors and the first, second, and third micro light-emitting diodes, and a second insulation layer defining the pocket pattern and surrounding a side surface of the two-dimensional semiconductor material layer, where the second insulation layer may be thicker than the two-dimensional semiconductor material layer.

In an embodiment, a thickness of the two-dimensional semiconductor material layer may be 0.1 nanometer (nm) to 10 nm.

In an embodiment, the ion-doped insulating partition may include GaN, InGaN, or a combination thereof doped with nitrogen ions, argon ions, boron ions, phosphorus ions, arsenic ions, or a combination thereof.

In an embodiment, each of the first, second, and third micro light-emitting diodes may include a P-type layer including a p-type semiconductor, a quantum well layer, and an N-type layer including an n-type semiconductor, wherein at least one selected from the P-type layer or the N-type layer and the quantum well layer may be surrounded by the ion-doped insulating partition.

In an embodiment, the two-dimensional semiconductor material may include metal chalcogenide, and has a monocrystalline, pseudo-monocrystalline, or polycrystalline structure.

An embodiment of a manufacturing method of a display panel according to the invention includes forming a thin film for an active layer of a micro light-emitting diode on an epi-wafer, implanting ions into a partial area of the thin film for the active layer of the micro light-emitting diode to form an ion-doped insulating partition in an area into which the ions are implanted and an active layer including a quantum well layer in an area into which the ions are not implanted, forming a first electrode of the micro light-emitting diode on the active layer, forming an insulation layer on the first electrode of the micro light-emitting diode, forming a two-dimensional semiconductor material layer on the insulation layer, forming a source electrode and a drain electrode, which are electrically connected to the two-dimensional semiconductor material layer, and forming a gate electrode overlapping the two-dimensional semiconductor material layer.

In an embodiment, the thin film for the active layer of the micro light-emitting diode may include a thin film for an N-type layer, a thin film for the quantum well layer, and a thin film for a P-type layer, and the implanting the ions may include supplying ions selected from nitrogen ions, argon ions, boron ions, phosphorus ions, arsenic ions, or a combination thereof to the thin film for the quantum well layer and at least one selected from the thin film for the N-type layer or the thin film for the P-type layer.

In an embodiment, the forming the insulation layer may include forming a first insulation layer, forming a second insulation layer including a material different from the first insulation layer, and patterning the second insulation layer to form a pocket pattern exposing the first insulation layer, wherein the forming the two-dimensional semiconductor material layer may include growing a two-dimensional semiconductor material in the pocket pattern.

In an embodiment, the forming the two-dimensional semiconductor material layer may include growing a metal chalcogenide at a temperature of about 400° C. or lower.

In an embodiment, the manufacturing method of the display panel may further include the attaching a support substrate to a surface of the gate electrode, removing the epi-wafer, and forming a second electrode of the micro light-emitting diode electrically connected to the active layer.

In an embodiment, an electronic device may include the display panel.

In embodiments, processes may be simplified without transfer and bonding processes, and a monolithic micro light-emitting diode display panel having high resolution and good performance may be implemented.

### BRIEF DESCRIPTION OF THE DRAWINGS

FIG. 1 is a top plan view showing an example of a display panel according to an embodiment.

FIG. 2 is a cross-sectional view showing an example of adjacent subpixels PX1, PX2, and PX3 of a display panel according to an embodiment.

FIG. 3 to FIG. 11 are drawings sequentially showing an example of a manufacturing method of a display panel according to an embodiment.

### DETAILED DESCRIPTION

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the invention to those skilled in the art.

In the drawings, the thickness of layers, films, panels, regions, etc., are exaggerated for clarity. It will be understood that when an element such as a layer, film, region, or substrate is referred to as being “above” or “on” another element, it can be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within +10%, +5%, +3%, or +1% of the indicated value or within a standard deviation.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

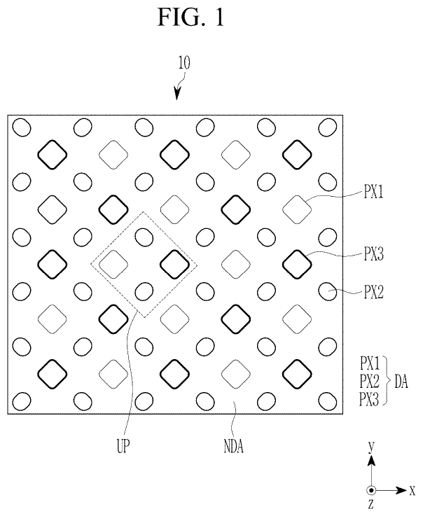

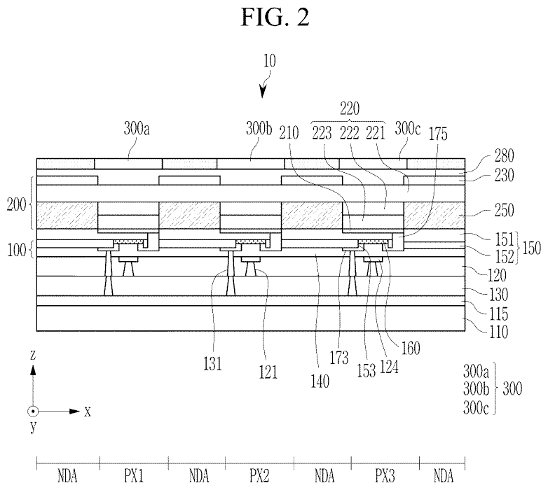

Hereinafter, a display panel according to an embodiment will be described. FIG. 1 is a top plan view showing an example of a display panel according to an embodiment, and FIG. 2 is a cross-sectional view showing an example of adjacent subpixels PX1, PX2, and PX3 of a display panel according to an embodiment.

Referring to FIG. 1, a display panel according to an embodiment 10 may include a subpixel array including first, second, and third subpixels PX1, PX2, and PX3, which are adjacent to each other. The first, second, and third subpixels PX1, PX2, and PX3 may display a same color as each other or different colors from each other, and for example, may display different colors. In an embodiment, for example, the first, second, and third subpixels PX1, PX2, and PX3 may display different colors, respectively, and each of the first, second, and third subpixels PX1, PX2, and PX3 may display one color of three primary colors, respectively. In an embodiment, for example, a first subpixel PX1 may be a blue subpixel for displaying blue (e.g., a subpixel that emits blue light), a second subpixel PX2 may be a green subpixel for displaying green (e.g., a subpixel that emits green light), and a third subpixel PX3 may be a red subpixel for displaying red (e.g., a subpixel that emits red light). However, the disclosure is not limited thereto, and in another embodiment, an auxiliary subpixel (not shown) such as a white subpixel may be further included. The first subpixel PX1, the second subpixel PX2 and the third subpixel PX3 include first, second, and third thin film transistors 100, and first, second, and third micro light-emitting diodes 200 may be independently driven by the first, second, and third thin film transistors 100, respectively.

Referring to FIG. 2, a micro light-emitting diode 200 included in the first subpixel PX1, the second subpixel PX2 or the third subpixel PX3, and a thin film transistor 100 for driving the first subpixel PX1, the second subpixel PX2 or the third subpixel PX3 may overlap in a thickness direction (e.g., z-direction) of a substrate 110, and may be manufactured as a monolithic integration display panel without a process of transfer and/or bonding of the micro light-emitting diode 200 or the thin film transistor 100.

Referring to FIG. 1, at least one first subpixel PX1, at least one second subpixel PX2 and at least one third subpixel PX3 may form one unit pixel UP, and may be repeatedly arranged on an entire surface of a display panel 10 along rows and/or columns. FIG. 1 illustrates an embodiment where the unit pixel UP is formed of (or defined by) one first subpixel PX1, two second subpixels PX2, and one third subpixel PX3, but is not limited thereto. An area that is occupied by a plurality of first, second, and third subpixels PX1, PX2, and PX3 and through which colors are displayed by the plurality of first, second, and third subpixels PX1, PX2, and PX3 may be a display area DA for displaying an image. An area other than the display area DA may be a non-display area NDA.

Referring to FIG. 2, a display panel according to an embodiment 10 may include the substrate 110, an adhesive layer 115, interlayer insulating layers 120 and 130, the thin film transistor 100, an insulation layer 150, the micro light-emitting diode 200, an ion-doped insulating partition 250, a passivation layer 280, and a color conversion layer 300.

The substrate 110 may be a support substrate, and for example, glass substrate, polymer substrate, silicon substrate, sapphire substrate, metal substrate, or a combination thereof. The polymer substrate may include, for example, polycarbonate, polymethyl methacrylate, polyethylene terephthalate, polyethylene naphthalate, polyimide, polyamide, polyamideimide, polyethersulfone, polyorganosiloxane, styrene-ethylene-butylene-styrene, polyurethane, polyacryl, polyolefin, or a combination thereof, but is not limited thereto.

The adhesive layer 115, which is a layer capable of bonding or adhering the substrate 110 and the interlayer insulating layers 120 and 130 to one another, may include, for example, spin-on-glass (SOG), epoxy resin, ultraviolet (UV) curing resin, benzocyclobutene (BCB), or a combination thereof, but is not limited thereto.

The interlayer insulating layers 120 and 130 may be located between the thin film transistor 100 and the substrate 110, and may be provided with a plurality of via holes 121 and 131 defined or formed therethrough. The via holes 121 and 131 may be filled with a conductive material.

Between the interlayer insulating layers 120 and 130 and/or between the interlayer insulating layers 120 and 130 and the adhesive layer 115, a metal wire (not shown) may be disposed, or a conductive interconnect electrically connected to a metal wire may be formed. In an embodiment, for example, a portion (e.g., a data wire) of the metal wire may be electrically connected to a source electrode 173 of the thin film transistor 100, and another portion (e.g., a gate wire) of the metal wire may be electrically connected to a gate electrode 124 of the thin film transistor 100.

The thin film transistor 100 may include the gate electrode 124, a gate insulating layer 140, a two-dimensional semiconductor material layer 160, the source electrode 173, and a drain electrode 175.

The gate electrode 124 is electrically connected to a gate wire (not shown) that transfers the gate signal. The gate electrode 124 may include a low-resistance conductor, and for example, copper (Cu), molybdenum (Mo), aluminum (AI), nickel (Ni), gold (Au), silver (Ag), chromium (Cr), tantalum (Ta), titanium (Ti), an alloy thereof, or a combination thereof, but is not limited thereto. The gate electrode 124 may be defined by or formed of a single layer or two or more layers, that is, may have a single layer structure or a multilayer structure.

The gate insulating layer 140 may be interposed between the gate electrode 124 and a two-dimensional semiconductor material layer 160 to be described later, and the gate insulating layer 140 may be formed on the entire surface of the substrate 110. The gate insulating layer 140 may include an organic material, an inorganic material and/or organic/inorganic materials, and may include, for example, oxide, nitride and/or oxynitride, and may include, for example, silicon oxide, silicon nitride, silicon oxynitride, aluminum oxide, aluminum nitride, aluminum oxynitride, or a combination thereof, but is not limited thereto. The gate insulating layer 140 may be defined by or formed of a single layer or two or more layers, that is, may have a single layer structure or a multilayer structure.

The two-dimensional semiconductor material layer 160 may overlap the gate electrode 124 along the thickness direction (e.g., z-direction) of the substrate 110, and for example, may be an island-shaped pattern. The two-dimensional semiconductor material layer 160 may include a two-dimensional semiconductor material. As for the two-dimensional semiconductor material, among three axes (e.g., x-axis, y-axis, and z-axis), a dimension along one axis (e.g., z-axis) may be much smaller than a dimension along other two axes (e.g., x-axis and y-axis), and for example, may be a sheet-like semiconductor nanomaterial of which the height (thickness) is very small compared to the width and the length. The two-dimensional semiconductor material may be, for example, a monolayer material configured by atoms, and may be a crystalline material having a monocrystalline, pseudo-monocrystalline, or polycrystalline structure. In an embodiment, for example, the two-dimensional semiconductor material layer 160 may have a structure in which the monolayered two-dimensional semiconductor material are stacked by a quantity of one to ten, that is, a structure in which 1 to 10 layers are stacked one on another, where each of the layers is defined by a monolayered two-dimensional semiconductor material.

The two-dimensional semiconductor material may include, for example, at least one metal element and at least one semi-metal element and/or non-metal element. The metal element may be selected from, for example, molybdenum (Mo), tungsten (W), tantalum (Ta), niobium (Ni), cobalt (Co), titanium (Ti), iron (Fe)), manganese (Mn), gallium (Ga), hafnium (Hf), zinc (Zn), vanadium (V), indium (In), nickel (Ni), tin (Sn), platinum (Pt), chromium (Cr), copper (Cu), ruthenium (Ru), aluminum (AI), zirconium (Zr), rhodium (Rh), thallium (TI), iridium (Ir), palladium (Pd), rhenium (Re), cadmium (Cd), osmium (Os), lead (Pb), or a combination thereof, and the semi-metal element and/or non-metal element may be selected from, for example, sulfur(S), selenium (Se), tellurium (Te), oxygen (O), nitrogen (N), phosphorus (P), or a combination thereof, but is not limited thereto. In an embodiment, for example, the two-dimensional semiconductor material may include, metal chalcogenide including at least one metal element and at least one chalcogen element. Here, the chalcogenide is a chemical compound consisting of at least one chalcogen anion, such as sulfur(S), selenium (Se), and tellurium (Te), and at least one more electropositive element attached and is covalently bonded together and is amorphous or crystalline in nature.

The two-dimensional semiconductor material may include, for example, at least one selected from CuS, MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TaₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂, CoPS₃, CrPS₄, Cu₍₁₋ₓ₎CrₓP₂S₆, NiPS₃, Ta₂O₅, TasN₅, TaON, Nb₂O₅ (here, 0≤x≤1), or a combination thereof, but is not limited thereto.

The two-dimensional semiconductor material layer 160 may have a very thin thickness, may have a thickness of about 10 nanometers (nm) or less, for example, a thickness in a range of about 0.1 nm to about 10 nm, about 0.1 nm to about 9 nm, about 0.1 nm to about 8 nm, about 0.1 nm to about 7 nm, about 0.1 nm to about 6 nm, about 0.1 nm to about 5 nm, about 0.1 nm to about 4 nm, about 0.1 nm to about 3 nm, about 0.1 nm to about 2 nm, about 0.2 nm to about 10 nm, about 0.2 nm to about 9 nm, about 0.2 nm to about 8 nm, about 0.2 nm to about 7 nm, about 0.2 nm to about 6 nm, about 0.2 nm to about 5 nm, about 0.2 nm to about 4 nm, about 0.2 nm to about 3 nm, about 0.2 nm to about 2 nm, about 0.5 nm to about 9 nm, about 0.5 nm to about 8 nm, about 0.5 nm to about 7 nm, about 0.5 nm to about 6 nm, about 0.5 nm to about 5 nm, about 0.5 nm to about 4 nm, about 0.5 nm to about 3 nm, about 0.5 nm to about 2 nm, about 1 nm to about 9 nm, about 1 nm to about 8 nm, about 1 nm to about 7 nm, about 1 nm to about 6 nm, about 1 nm to about 5 nm, about 1 nm to about 4 nm, about 1 nm to about 3 nm, or about 1 nm to about 2 nm.

A width or length of the two-dimensional semiconductor material layer 160 may be less than about 1 micrometer (μm), for example, may be about 900 nm or less, about 800 nm or less, about 700 nm or less, about 600 nm or less, or about 500 nm or less, in a range of about 100 nm to about 1 μm, about 100 nm to about 900 nm, about 100 nm to about 800 nm, about 100 nm to about 700 nm, about 100 nm to about 600 nm, or about 100 nm to about 500 nm. Accordingly, in such an embodiment, a short channel thin film transistor 100 may be implemented.

The two-dimensional semiconductor material layer 160 may be surrounded by the insulation layer 150 within a pocket pattern 153 in the insulation layer 150, which will be described later.

The source electrode 173 and the drain electrode 175 may be electrically connected to the two-dimensional semiconductor material layer 160, respectively, and for example, may contact the two-dimensional semiconductor material layer 160, respectively.

The source electrode 173 may be electrically connected to a data wire (not shown) for transferring the data signal, and for example, may be electrically connected to the data wire through the via holes 121 and 131 defined or formed through the gate insulating layer 140 and the interlayer insulating layers 120 and 130. A drain electrode 175 is electrically connected to the micro light-emitting diode 200 to be described later.

The source electrode 173 and the drain electrode 175 may include a low-resistance conductor, and for example, copper (Cu), molybdenum (Mo), aluminum (Al), nickel (Ni), gold (Au), silver (Ag), chromium (Cr), tantalum (Ta), titanium (Ti), an alloy thereof, or a combination thereof, but is not limited thereto. The source electrode 173 and the drain electrode 175 may be defined by or formed of a single layer or two or more layers, that is, may have a single layer structure or a multilayer structure.

The insulation layer 150 may be between the thin film transistor 100 and the micro light-emitting diode 200, and the drain electrode 175 may be electrically connected to the micro light-emitting diode 200 by extending through the insulation layer 150.

The insulation layer 150 may include the pocket pattern 153 for providing a growth area of the above-mentioned two-dimensional semiconductor material layer 160. The pocket pattern 153 may be defined by an area in which the two-dimensional semiconductor material layer 160 is to be deposited and/or grown, and for example, may be a recess portion located in a partial area of the insulation layer 150.

The insulation layer 150 includes a first insulation layer 151 formed on the entire surface (excluding a portion electrically connecting the two-dimensional semiconductor material layer 160 and the micro light-emitting diode 200) between the two-dimensional semiconductor material layer 160 and the micro light-emitting diode 200, and a second insulation layer 152 of which a partial area is removed. The pocket pattern 153 may be an area in which the second insulation layer 152 is removed and the first insulation layer 151 is exposed. The pocket pattern 153 may be a space defined (or surrounded) by the first insulation layer 151, the second insulation layer 152 and the gate insulating layer 140.

In an embodiment, for example, the first insulation layer 151 may be in contact with a lower or upper portion of the two-dimensional semiconductor material layer 160, and may provide a base (e.g., bottom) on which two-dimensional semiconductor materials are grown, by being exposed through the pocket pattern 153. The second insulation layer 152 may partition an area where the two-dimensional semiconductor material is grown, and the two-dimensional semiconductor material may be grown in the pocket pattern 153 where the second insulation layer 152 is selectively removed. Accordingly, the second insulation layer 152 may surround a side surface of the two-dimensional semiconductor material layer 160, and for example, a planar shape of the two-dimensional semiconductor material may be substantially the same as a planar shape of the pocket pattern 153.

The first insulation layer 151 and the second insulation layer 152 may respectively include different insulating materials having different surface characteristics from each other, and for example, one of the first insulation layer 151 and the second insulation layer 152 may include silicon oxide, silicon nitride, silicon oxynitride, or a combination thereof, and the other of the first insulation layer 151 and the second insulation layer 152 may include oxide, nitride, oxynitride, or a combination thereof that includes hafnium (Hf), aluminum (AI), lanthanum (La), barium (Ba), strontium (Sr), zirconium (Zr), yttrium (Y), calcium (Ca), or a combination thereof, but is not limited thereto. In an embodiment, for example, the first insulation layer 151 may include oxide, nitride, oxynitride, or a combination thereof that includes hafnium (Hf), aluminum (Al), lanthanum (La), barium (Ba), strontium (Sr), zirconium (Zr), yttrium (Y), calcium (Ca), or a combination thereof, and the second insulation layer 152 may include silicon oxide, silicon nitride, silicon oxynitride, or a combination thereof. Accordingly, as will be described later, a two-dimensional semiconductor material may be selectively deposited and/or grown on the first insulation layer 151 exposed through the pocket pattern 153 when forming the two-dimensional semiconductor material layer 160.

The second insulation layer 152 may be thicker than the two-dimensional semiconductor material layer 160, and accordingly, the second insulation layer 152 may partition the area where the two-dimensional semiconductor material is grown more precisely, and the two-dimensional semiconductor material may be effectively deposited and/or grown within the pocket pattern 153. In an embodiment, for example, a thickness of the second insulation layer 152 may be in a range of about 3 times or more of a thickness of the two-dimensional semiconductor material layer 160, for example, may be in a range of about 3 times to 100 times, about 3 times to 90 times, about 3 times to 80 times, about 3 times to 50 times, about 5 times to 100 times, about 5 times to 90 times, about 5 times to 80 times, about 5 times to 50 times, about 10 times to 100 times, about 10 times to 90 times, about 10 times to 80 times, or about 10 times to 50 times of the thickness of the two-dimensional semiconductor material layer 160.

Each of thicknesses of the first insulation layer 151 and of the second insulation layer 152 may be, for example, more than about 10 nm and about 1 μm or less, and for example, may be in a range of about 12 nm to about 1 μm, about 12 nm to about 800 nm, about 12 nm to about 500 nm, about 12 nm to about 300 nm, about 12 nm to about 200 nm, about 12 nm to about 150 nm, or about 12 nm to about 100 nm. In an embodiment, for example, the second insulation layer 152 may be thinner than the first insulation layer 151.

The micro light-emitting diode 200 is located on the insulation layer 150. The micro light-emitting diode 200 includes a first electrode 210 electrically connected to the thin film transistor 100, an active layer 220, and a second electrode 230.

Each of the first electrode 210 and the second electrode 230 may be a light transmissive electrode or reflective electrode, and for example, at least one selected from the first electrode 210 or the second electrode 230 may be a light transmissive electrode. In an embodiment, for example, the first electrode 210 may be a reflective electrode, and accordingly, may be configured to reflect the light emitted by the active layer 220 in a direction toward the color conversion layer 300. In an embodiment, for example, the second electrode 230 may be a light transmissive electrode, and accordingly, may be configured to transmit the light emitted by the active layer 220. The light transmissive electrode may include, for example, indium tin oxide (ITO), indium zinc oxide (IZO), indium gallium zinc oxide (IGZO), or a combination thereof, but is not limited thereto. The reflective electrode may include, for example, Ag, Au, Al, Cr, Ni, an alloy thereof, or a combination thereof, but is not limited thereto.

The first electrode 210 may be a pixel electrode electrically connected to the thin film transistor 100 located at each of the subpixels PX1, PX2, and PX3 and independently applied with a voltage. In an embodiment, for example, the second electrode 230 may be a common electrode to which a common voltage is applied. One of the first electrode 210 and the second electrode 230 may be an anode, and the other of the first electrode 210 and the second electrode 230 may be a cathode.

The active layer 220 may be electrically connected to the first electrode 210 and the second electrode 230, respectively, and includes a first semiconductor layer 221, a quantum well layer 222 and a second semiconductor layer 223. One of the first semiconductor layer 221 and the second semiconductor layer 223 may be an N-type layer, and the other of the first semiconductor layer 221 and the second semiconductor layer 223 may be a P-type layer. The N-type layer may be a semiconductor layer doped with an N-type dopant, and for example, may be n-GaN, n-InGaN, or a combination thereof, but is not limited thereto. The P-type layer may be a semiconductor layer doped with a P-type dopant, and for example, may be p-GaN, p-InGaN, or a combination thereof, but is not limited thereto. In an embodiment, for example, the first semiconductor layer 221 may be the N-type layer, and the second semiconductor layer 223 may be the P-type layer.

The quantum well layer 222, which is a layer where electrons and holes are combined to emit light, may have, for example, a multi-quantum well (MQW) or single-quantum well (SQW) structure. The quantum well layer 222 may include, for example, a group III-V semiconductor, and may include, for example, GaN, InGaN, or a combination thereof, and for example, may include a GaN layer and an InGaN layer.

At least a portion of the active layer 220 may be surrounded by the ion-doped insulating partition 250. In an embodiment, for example, the quantum well layer 222 may be surrounded by the ion-doped insulating partition 250, and in addition, at least one of the first semiconductor layer 221 or the second semiconductor layer 223 may be surrounded by the ion-doped insulating partition 250. FIG. 2 shows an embodiment where the quantum well layer 222 and the second semiconductor layer 223 are surrounded by the ion-doped insulating partition 250 as an example, but is not limited thereto.

The ion-doped insulating partition 250 may have insulating properties by doping a semiconductor material that is the same as the active layer 220 with a predetermined ion. In an embodiment, for example, as will be described later, the ion-doped insulating partition 250 having the insulating properties may be formed by forming a thin film for the active layer 220 and by implanting the predetermined ion into only a partial area (e.g., the area other than the active layer 220) of the thin film for the active layer 220. Herein, for example, the predetermined ion may be an inert ion, a P-type ion, an N-type ion, or a combination thereof. Accordingly, the ion-doped insulating partition 250 may include the doped ions and the semiconductor material of the active layer 220, and for example, GaN, InGaN, or a combination thereof may be doped with nitrogen (N) ion, Argon (Ar) ion, boron (B) ion, phosphorus (P) ion, arsenic (As) ion, or a combination thereof.

The ion-doped insulating partition 250 does not flow current and does not emit light, and may perform the function of separating the quantum well layer 222 of the micro light-emitting diode 200 of each of the subpixels PX1, PX2, and PX3. As will be described later, since the ion-doped insulating partition 250 may be formed, for example, by tailored ion implantation into a partial area (e.g., each area between the subpixels PX1, PX2, and PX3) during a process of forming the active layer 220, without etching and/or additional patterning of the quantum well layer 222 and the first and/or second semiconductor layers 221 and 223, a partitioned micro light-emitting diode 220 may be formed at each of the subpixels PX1, PX2, and PX3.

The passivation layer 280 is located on the micro light-emitting diode 200. The passivation layer 280 may planarize the micro light-emitting diode 200, may include, for example, an organic material, an inorganic material and/or organic/inorganic materials, and may be defined by or formed of, for example, a single layer or two or more layers, that is, may have a single layer structure or a multilayer structure.

The color conversion layer 300 is located on the passivation layer 280. The color conversion layer 300 may be configured to transmit the light emitted from the micro light-emitting diode 200 or convert the light emitted from the micro light-emitting diode 200 to the light in a different wavelength spectrum. In an embodiment, for example, the micro light-emitting diode 200 may be configured to emit light in an ultraviolet (UV) wavelength spectrum to a blue wavelength spectrum, and the color conversion layer 300 may be configured to convert light in the blue wavelength spectrum to the light in a blue, green, or red wavelength spectrum. Accordingly, the display panel 10 may be a full color display panel.

In an embodiment, for example, when the first subpixel PX1 is the blue subpixel for displaying blue, a color conversion layer 300a included in the first subpixel PX1 may pass the light in the blue wavelength spectrum or convert the light in the blue wavelength spectrum to the light in the blue wavelength spectrum, and for example, when the second subpixel PX2 is the green subpixel for displaying green, a color conversion layer 300b included in the second subpixel PX2 may be configured to convert the light in the blue wavelength spectrum to the light in a green wavelength spectrum, and when the third subpixel PX3 is the red subpixel for displaying red, a color conversion layer 300c may be configured to convert the light in the blue wavelength spectrum to the light in a red wavelength spectrum. Herein, light emitting peak wavelengths of light emitting spectrums of the ultraviolet (UV) wavelength spectrum, the blue wavelength spectrum, the green wavelength spectrum and the red wavelength spectrum may be in a range of about 250 nm to 380 nm, more than about 380 nm and less than 500 nm, about 500 nm to 600 nm, and more than about 600 nm to 750 nm, respectively.

The color conversion layer 300 may include, for example, a quantum dot, a phosphor, or a combination thereof. The quantum dot may have photoluminescence characteristics, may include, for example, group II-VI semiconductor, group III-V semiconductor, group IV-VI semiconductor, group IV semiconductor, or a combination thereof, but is not limited thereto.

Hereinafter, a manufacturing method of the above-mentioned display panel 10 according to an embodiment will be described with reference to the drawings.

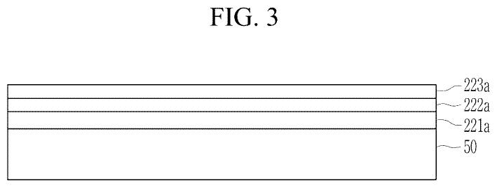

FIG. 3 to FIG. 11 are drawings sequentially showing an example of a manufacturing method of a display panel according to an embodiment.

Referring to FIG. 3, thin films 221a, 222a, and 223a for an active layer of the micro light-emitting diode 200 are sequentially formed on an epi-wafer 50. The epi-wafer 50 may be, for example, a silicon wafer, a GaN wafer, and/or a GaAs wafer. A first thin film 221a may be a thin film for the first semiconductor layer for the N-type layer or the P-type layer, a second thin film 222a may be a thin film for the quantum well layer, and a third thin film 223a may be a thin film for second semiconductor layer for the P-type layer or the N-type layer. In an embodiment, for example, the first thin film 221a may be formed by growing n-GaN, n-InGaN, or a combination thereof, and the second thin film 222a may be formed by growing GaN, InGaN, or a combination thereof, and the third thin film 223a may be formed by growing p-GaN, p-InGaN, or a combination thereof. One or more buffer layers (not shown) may be additionally formed between the epi-wafer 50 and the thin films 221a, 222a, and 223a for the active layer, and for example, the buffer layer may be formed by growing oxide, nitride, or oxynitride including a metal such as aluminum, but is not limited thereto.

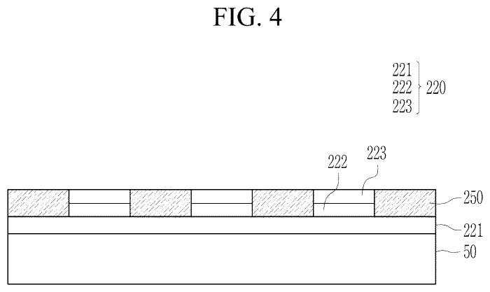

Referring to FIG. 4, a mask (not shown) is disposed on the thin films 221a, 222a, and 223a for an active layer of the micro light-emitting diode 200, and ions are implanted into a partial area of the thin films 221a, 222a, and 223a for the active layer. In an embodiment, for example, the ions may be nitrogen ions, argon ions, phosphorus ions, boron ions, arsenic ions, or a combination thereof, but is not limited thereto. The area where the ion are implanted, which is each area between the subpixels PX1, PX2, and PX3, may be the area other than the display area DA, that is, the non-display area NDA. The area in the thin films 221a, 222a, and 223a for the active layer where the ions are implanted does not have semiconductor properties any more due to the ion implantation but has the electrical insulating properties instead, and may define or be formed as the ion-doped insulating partition 250 that partitions the active layer 220 of the micro light-emitting diode 200 of each of the subpixels PX1, PX2, and PX3. In an embodiment, the area of the thin films 221a, 222a, and 223a for the active layer where the ions are not implanted may define or be formed as the active layer 220 of the micro light-emitting diode 200 that is partitioned at each of the subpixels PX1, PX2, and PX3. In an embodiment, as shown in FIG. 4, the ion-doped insulating partition 250 partitions the quantum well layer 222 and the second semiconductor layer 223, but it is not limited thereto. In another embodiment, the ion-doped insulating partition 250 may partition the first semiconductor layer 221 and the quantum well layer 222 or may partition the first semiconductor layer 221, partition the quantum well layer 222, and the second semiconductor layer 223.

In such an embodiment, by changing electrical properties by implanting ions into a partial area of the thin films 221a, 222a, and 223a for the active layer, the active layer 220 of the micro light-emitting diode 200 of each of the subpixels PX1, PX2, and PX3 may be partitioned without etching and/or patterning of the thin films 221a, 222a, and 223a for the active layer.

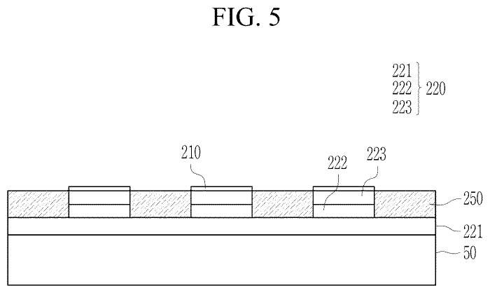

Referring to FIG. 5, the first electrode 210 is formed on the active layer 220 of the micro light-emitting diode 200. The first electrode 210 may be formed by depositing a light transmissive conductor or a light non-transmissive conductor. The light transmissive conductor may be, for example, ITO, IZO, IGZO, or a combination thereof, and for example, the light non-transmissive conductor may be Ag, Au, Al, Cr, Ni, an alloy thereof, or a combination thereof, but is not limited thereto.

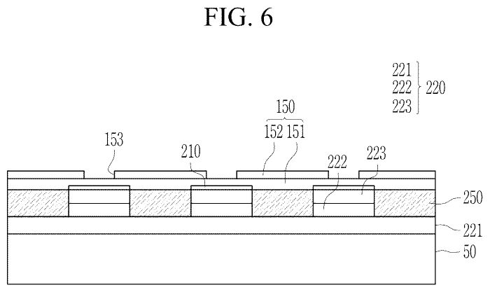

Referring to FIG. 6, the insulation layer 150 is formed on the entire surface including the ion-doped insulating partition 250 and the first electrode 210 of the micro light-emitting diode 200. The insulation layer 150 may include the first insulation layer 151 and the second insulation layer 152, which are formed of different insulating materials, respectively.

First, the first insulation layer 151 is formed on the entire surface including the ion-doped insulating partition 250 and the first electrode 210 of the micro light-emitting diode 200. Subsequently, the second insulation layer 152 having the pocket pattern 153 is formed at a location corresponding to the micro light-emitting diode 200 on the first insulation layer 151. The pocket pattern 153 is a portion where the second insulation layer 152 is removed, and exposes the first insulation layer 151.

The first insulation layer 151 and the second insulation layer 152 may be formed by sequentially depositing different insulating materials, and for example, may be formed by using a chemical vapor deposition method.

In an embodiment, for example, the pocket pattern 153 may be formed by photolithography after depositing an insulation layer for the second insulation layer 152 on the first insulation layer 151. A width and/or length of the pocket pattern 153 may be less than about 1 μm, for example, may be about 900 nm or less, about 800 nm or less, about 700 nm or less, about 600 nm or less, or about 500 nm or less, in a range of about 100 nm to about 1 μm, about 100 nm to about 900 nm, about 100 nm to about 800 nm, about 100 nm to about 700 nm, about 100 nm to about 600 nm, or about 100 nm to about 500 nm. The width and length of the pocket pattern 153 may be the same as the width and length of the two-dimensional semiconductor material layer 160 of the thin film transistor 100.

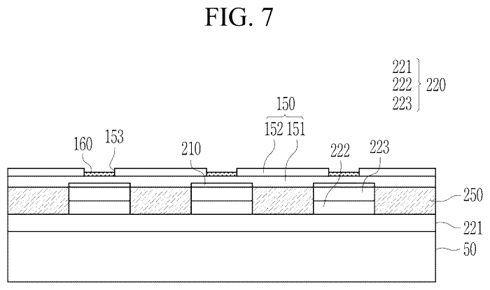

Referring to FIG. 7, by depositing and growing the two-dimensional semiconductor material on the insulation layer 150, a two-dimensional semiconductor layer 160 may be formed within the pocket pattern 153. The two-dimensional semiconductor material may be selectively deposited and grown on a portion of the first insulation layer 151 exposed through the pocket pattern 153. The two-dimensional semiconductor material may be, for example, metal chalcogenide. In an embodiment, for example, the metal chalcogenide may be formed by forming a metal seed film and by supplying the chalcogen element through, for example, chemical vapor deposition, but is not limited thereto. However, the two-dimensional semiconductor layer 160 may be deposited and/or grown from various materials and by using various methods.

The two-dimensional semiconductor material may be grown at a comparatively low temperature, and may be grown at a temperature below about 400° C., for example, a temperature about 30° C. or more and less than about 400° C., about 50° C. or more and less than about 400° C., about 80° C. or more and less than about 400° C., about 100° C. or more and less than about 400° C., about 150° C. or more and less than about 400° C., in a range of about 30° C. to about 380° C., about 50° C. to about 380° C., about 80° C. to about 380° C., about 100° C. to about 380° C., about 150° C. to about 380° C., about 100° C. to about 350° C., about 30° C. to about 350° C., about 50° C. to about 350° C., about 80° C. to about 350° C., about 100° C. to about 350° C., or about 150° C. to about 350° C. The two-dimensional semiconductor material may be grown to have a monocrystalline, pseudo-monocrystalline, and/or polycrystalline structure.

In such an embodiment, by forming the two-dimensional semiconductor material layer 160 to the monocrystalline, pseudo-monocrystalline, and/or polycrystalline structure at a comparatively low temperature, degradation due to heat to which the active layer 220 of the above-mentioned micro light-emitting diode 200 is exposed in subsequent process may be substantially reduced or effectively prevented, degradation of performance of the micro light-emitting diode 200 may be effectively prevented, and at the same time, the thin film transistor channel of high quality may be implemented.

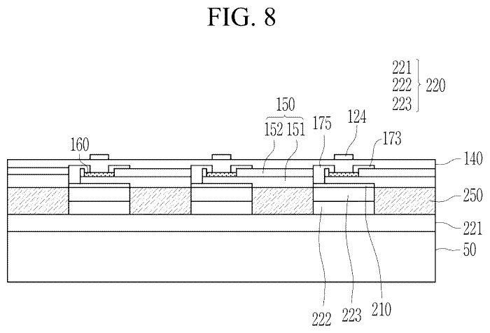

Referring to FIG. 8, the source electrode 173 and the drain electrode 175 electrically connected to the two-dimensional semiconductor layer 160 are formed, and the gate insulating layer 140 is formed thereon. Subsequently, the gate electrode 124 is formed on the gate insulating layer 140.

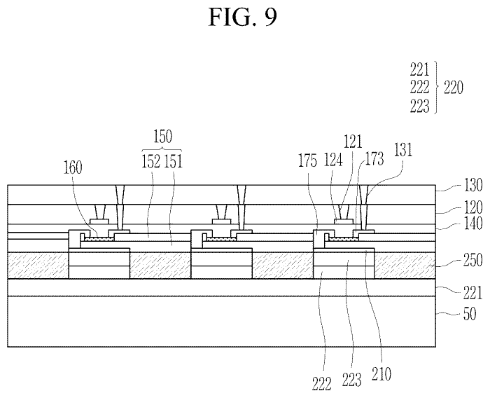

Referring to FIG. 9, the interlayer insulating layers 120 and 130 are sequentially formed on the gate electrode 124. In an embodiment, for example, the interlayer insulating layers 120 and 130 may be formed by chemical vapor deposition, but is not limited thereto. The interlayer insulating layers 120 and 130 may be provided with the plurality of via holes 121 and 131, and the via holes 121 and 131 may be filled with a conductive material. Between the interlayer insulating layers 120 and 130 and/or between the interlayer insulating layers 120 and 130 and the adhesive layer 115, a metal wire (not shown) may be formed, or a conductive interconnect electrically connected to the metal wire may be formed.

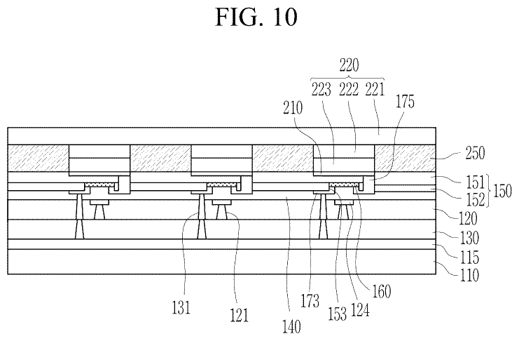

Referring to FIG. 10, a support substrate 110 is attached to a first surface of the interlayer insulating layers 120 and 130. The support substrate 110 may be attached to the interlayer insulating layers 120 and 130 by interposing the adhesive layer 115, but is not limited thereto, and may be attached by plasma surface treatment or the like. Subsequently, the epi-wafer 50 is removed by detaching the epi-wafer 50 from the first semiconductor layer 221.

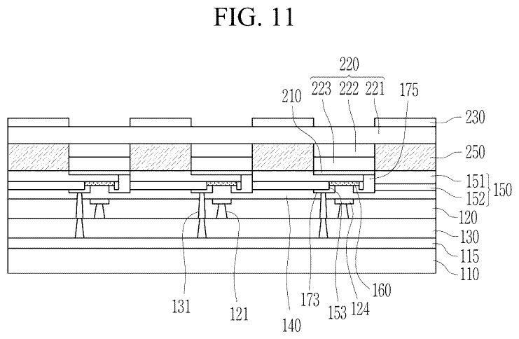

Referring to FIG. 11, the second electrode 230 is formed on the first semiconductor layer 221.

Lastly, referring back to FIG. 2, the display panel 10 is manufactured by sequentially form the passivation layer 280 and the color conversion layer 300 on the second electrode 230.

According to embodiments of a display panel 10, as described above, the thin film transistor 100 and the micro light-emitting diode 200 may be formed on one substrate by a monolithic integration method without performing a transfer and bonding process.

According to embodiments of a display panel 10, by changing electrical properties of a partial area of the thin films 221a, 222a, and 223a for the active layer by implanting ions into the partial area of the thin films 221a, 222a, and 223a for the active layer, the active layer 220 of the micro light-emitting diode 200 may be partitioned into each of the subpixels PX1, PX2, and PX3 without etching and/or patterning of the thin films 221a, 222a, and 223a for the active layer.

In such embodiments, by forming the micro light-emitting diode 200 by partitioning into each of the subpixels PX1, PX2, and PX3 without separate etching and/or patterning, the two-dimensional semiconductor material may be directly grown on a substantially flat structure, and a channel of the thin film transistor 100 of high quality may be implemented.

In such embodiments, by effectively growing the two-dimensional semiconductor material of a monocrystalline, pseudo-monocrystalline, and/or polycrystalline structure at a comparatively low temperature (below about 400° C.) by using the pocket pattern 153, thermal degradation of the active layer of the micro light-emitting diode due to subsequent processes may be substantially reduced or effectively prevented, degradation of the micro light-emitting diode 200 may be effectively prevented, and at the same time, a high-performance thin film transistor may be implemented without the limitation of a short channel effect. Accordingly, the subpixels PX1, PX2, and PX3 with small dimensions may be formed without limitation of performance and/or dimension of the micro light-emitting diode and thin film transistor, and accordingly, high-resolution micro light-emitting diode display panel of 8000 pixels per inch (ppi) or more having high charge mobility may be implemented.

The above-mentioned display panel may be applied to various electronic devices including a display device. Electronic devices including display devices may be, for example, mobile phones, video phones, smart phones, mobile phones, smart pads, smart watches, digital cameras, tablet computers, laptop computers, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT) device, Internet of Everything (IoE) device, drones, door locks, safes, automated teller machines (ATM), security devices, medical devices, or automotive electronic components, but are not limited thereto.

The disclosure should not be construed as being limited to the embodiments set forth herein. Rather, these embodiments are provided so that this disclosure will be thorough and complete and will fully convey the concept of the invention to those skilled in the art.

While the disclosure has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel, comprising:
a substrate,
a gate electrode disposed on the substrate,
a two-dimensional semiconductor material layer overlapping the gate electrode,
a source electrode and a drain electrode electrically connected to the two-dimensional semiconductor material layer,
a first electrode of a micro light-emitting diode electrically connected to the drain electrode,
an active layer electrically connected to the first electrode of the micro light-emitting diode, wherein the active layer comprises a quantum well layer surrounded by an ion-doped insulating partition, and
a second electrode of the micro light-emitting diode electrically connected to the active layer.

2. The display panel of claim 1, further comprising:
a first insulation layer disposed between the first electrode of the micro light-emitting diode and the two-dimensional semiconductor material layer and contacting a lower portion or an upper portion of the two-dimensional semiconductor material layer, and
a second insulation layer surrounding a side surface of the two-dimensional semiconductor material layer,
wherein the second insulation layer is thicker than the two-dimensional semiconductor material layer.

3. The display panel of claim 2, wherein a thickness of the second insulation layer is 3 times to 100 times of a thickness of the two-dimensional semiconductor material layer.

4. The display panel of claim 2, wherein
one of the first insulation layer and the second insulation layer includes silicon oxide, silicon nitride, silicon oxynitride, or a combination thereof, and
the other of the first insulation layer and the second insulation layer includes oxide, nitride, oxynitride, or a combination thereof that includes hafnium (Hf), aluminum (AI), lanthanum (La), barium (Ba), strontium (Sr), zirconium (Zr), yttrium (Y), calcium (Ca), or a combination thereof.

5. The display panel of claim 1, wherein the two-dimensional semiconductor material layer includes metal chalcogenide and has a monocrystalline, pseudo-monocrystalline, or polycrystalline structure.

6. The display panel of claim 1, wherein the active layer further comprises:
an N-type layer disposed in one of an upper portion and a lower portion of the quantum well layer, and
a P-type layer disposed in the other of the upper portion and the lower portion of the quantum well layer,
wherein at least one selected from the N-type layer or the P-type layer is surrounded by the ion-doped insulating partition.

7. The display panel of claim 1, wherein the ion-doped insulating partition includes GaN, InGaN, or a combination thereof doped with nitrogen ions, argon ions, boron ions, phosphorus ions, arsenic ions, or a combination thereof.

8. The display panel of claim 1, further comprising:
an interlayer insulating layer disposed between the substrate and the source electrode, and
a conductive interconnect disposed through the interlayer insulating layer and connecting the source electrode and a wire to each other.

9. A display panel comprising:
first, second, and third thin film transistors disposed in first, second, and third subpixels, respectively, wherein the first, second, and third subpixels are adjacent to each other,
first, second, and third micro light-emitting diodes disposed in the first, second, and third subpixels, respectively, and electrically connected to the first, second, and third thin film transistors, respectively,
an ion-doped insulating partition partitioning the first, second, and third micro light-emitting diodes, and
an insulation layer disposed between the first, second, and third thin film transistors and the first, second, and third micro light-emitting diodes and including a plurality of pocket patterns defined therein,
wherein each of the first, second, and third thin film transistors includes a two-dimensional semiconductor material layer, and
wherein the two-dimensional semiconductor material layer is disposed in the pocket pattern of the insulation layer.

10. The display panel of claim 9, wherein the insulation layer comprises:
a first insulation layer disposed on an entire surface between the first, second, and third thin film transistors and the first, second, and third micro light-emitting diodes, and
a second insulation layer defining the pocket pattern and surrounding a side surface of the two-dimensional semiconductor material layer,
wherein the second insulation layer is thicker than the two-dimensional semiconductor material layer.

11. The display panel of claim 9, wherein a thickness of the two-dimensional semiconductor material layer is in a range of about 0.1 nm to about 10 nm.

12. The display panel of claim 9, wherein, the ion-doped insulating partition includes GaN, InGaN, or a combination thereof doped with nitrogen ions, argon ions, boron ions, phosphorus ions, arsenic ions, or a combination thereof.

13. The display panel of claim 9, wherein each of the first, second, and third micro light-emitting diodes comprises:
a P-type layer comprising a p-type semiconductor,
a quantum well layer, and
an N-type layer comprising an n-type semiconductor,
wherein at least one selected from the P-type layer or the N-type layer and the quantum well layer are surrounded by the ion-doped insulating partition.

14. The display panel of claim 9, wherein the two-dimensional semiconductor material includes metal chalcogenide, and has a monocrystalline, pseudo-monocrystalline, or polycrystalline structure.

15. A manufacturing method of a display panel, the manufacturing method comprising:
forming a thin film for an active layer of a micro light-emitting diode on an epi-wafer,
implanting ions into a partial area of the thin film for the active layer of the micro light-emitting diode to form an ion-doped insulating partition in an area into which the ions are implanted and an active layer including a quantum well layer in an area into which the ions are not implanted,
forming a first electrode of the micro light-emitting diode on the active layer,
forming an insulation layer on the first electrode of the micro light-emitting diode,
forming a two-dimensional semiconductor material layer on the insulation layer,
forming a source electrode and a drain electrode, which are electrically connected to the two-dimensional semiconductor material layer, and forming a gate electrode overlapping the two-dimensional semiconductor material layer.

16. The manufacturing method of claim 15, wherein
the thin film for the active layer of the micro light-emitting diode comprises a thin film for an N-type layer, a thin film for the quantum well layer, and a thin film for a P-type layer, and
the implanting the ions comprises supplying ions selected from nitrogen ions, argon ions, boron ions, phosphorus ions, arsenic ions, or a combination thereof to the thin film for the quantum well layer and at least one selected from the thin film for the N-type layer or the thin film for the P-type layer.

17. The manufacturing method of claim 15, wherein the forming the insulation layer comprises:
forming a first insulation layer,
forming a second insulation layer comprising a material different from the first insulation layer, and
patterning the second insulation layer to form a pocket pattern exposing the first insulation layer,
wherein the forming the two-dimensional semiconductor material layer comprises growing a two-dimensional semiconductor material in the pocket pattern.

18. The manufacturing method of claim 15, wherein the forming the two-dimensional semiconductor material layer comprises growing a metal chalcogenide at a temperature of about 400° C. or lower.

19. The manufacturing method of claim 15, further comprising:
attaching a support substrate to a surface of the gate electrode,
removing the epi-wafer, and
forming a second electrode of the micro light-emitting diode electrically connected to the active layer.

20. An electronic device comprising a display panel according to claim 1.
